(19) United States
(12) Patent Application Publication
(10) Pub. No.: US 2024/0222258 A1
(43) Pub. Date: Jul. 4, 2024

(54) GLASS SUBSTRATES WITH SELF-ASSEMBLED MONOLAYERS FOR COPPER ADHESION

(71) Applicant: Intel Corporation, Santa Clara, CA (US)

(72) Inventors: Rachel Guia Parala Giron, Mesa, AZ (US); Darko Grujicic, Chandler, AZ (US); Suddhasattwa Nad, Chandler, AZ (US)

(21) Appl. No.: 18/092,012

(22) Filed: Dec. 30, 2022

(51) Int. Cl. H01L 23/498; H01L 21/48

(52) U.S. Cl. CPC H01L 23/49894; H01L 21/4857; H01L 23/49822

(57) ABSTRACT

Glass substrates with self-assembled monolayers for copper adhesion, and methods of forming the same, are described herein. In one example, a substrate includes one or more glass layers, a self-assembled monolayer on the one or more glass layers, and a conductive layer on the self-assembled monolayer. The conductive layer includes copper, and the self-assembled monolayer is between the one or more glass layers and the conductive layer.

### BACKGROUND

Glass has become an increasingly attractive option for use as the core of semiconductor substrates, such as package substrates and printed circuit boards (PCBs). However, a glass core generally does not bond well with subsequent functional layers of a substrate, such as copper seed layers. As a result, metallization of a glass core may require intervening adhesive layers, such as layers of titanium, to be formed between the glass core and the copper seed layers to provide adhesion. These adhesive titanium layers can be relatively thick, however, which increases the size of the resulting substrate and integrated circuit package.

### BRIEF DESCRIPTION OF THE DRAWINGS

FIG. 1 illustrates a cross-section view of a substrate with a glass core and self-assembled monolayers to provide adhesion to copper seed layers in accordance with certain embodiments.

FIGS. 2A-2E illustrate a process flow for forming a glass substrate with a self-assembled monolayer and a copper seed layer in accordance with certain embodiments.

FIGS. 3A-3D illustrate the molecular structure of various representative organosilanes that may be used to form self-assembled monolayers on glass substrates.

FIG. 4 illustrates a flowchart for forming an integrated circuit (IC) package on a substrate with a glass core and self-assembled monolayers for adhesion to copper seed layers.

FIG. 5 illustrates an example of a package substrate with a glass core and self-assembled monolayers in accordance with certain embodiments.

FIG. 6 illustrates an example of a multi-die package on a substrate with a glass core and self-assembled monolayers in accordance with certain embodiments.

FIG. 7 illustrates a cross-section view of an electronic device in accordance with certain embodiments.

FIG. 8 is a top view of a wafer and dies that may be included in a microelectronic assembly in accordance with certain embodiments.

FIG. 9 is a cross-sectional side view of an integrated circuit device that may be included in a microelectronic assembly in accordance with certain embodiments.

FIG. 10 is a cross-sectional side view of an integrated circuit device assembly that may include a microelectronic assembly in accordance with certain embodiments.

FIG. 11 is a block diagram of an example electrical device that may include a microelectronic assembly in accordance with certain embodiments.

### DETAILED DESCRIPTION

Glass has become an increasingly attractive option for use as the core of semiconductor substrates, such as package substrates and printed circuit boards (PCBs). However, a glass core generally does not bond well with subsequent functional layers of a substrate, such as copper seed layers. As a result, metallization of a glass core may require intervening adhesive layers to be formed between the glass core and the copper seed layers to provide adhesion. In some cases, for example, layers of titanium may be used as the adhesion promotor between the glass core and copper seed layers. These adhesive titanium layers typically have a thickness of around 50 nanometers (nm), however, which increases the overall package size. As a result, it is desirable to reduce the thickness of these adhesive layers to decrease the package size. While the use of more sophisticated tools could potentially reduce the thickness of these adhesive titanium layers to roughly 20 nm, any further reductions in thickness would be very difficult to achieve.

Accordingly, this disclosure presents embodiments of glass core substrates that include self-assembled monolayers on the glass core as adhesion promoters to enable deposition of copper seed layers. For example, rather than forming relatively thick layers of titanium on the glass core for adhesion to the copper seed layers, self-assembled monolayers can be formed on the glass core using organosilanes. These self-assembled monolayers not only promote adhesion between the glass core and the copper seed layers, but they can be formed with a thickness as low as 0.5-1 nm, which is significantly thinner than adhesive titanium layers. As a result, the size of the resulting substrate and integrated circuit package is reduced.

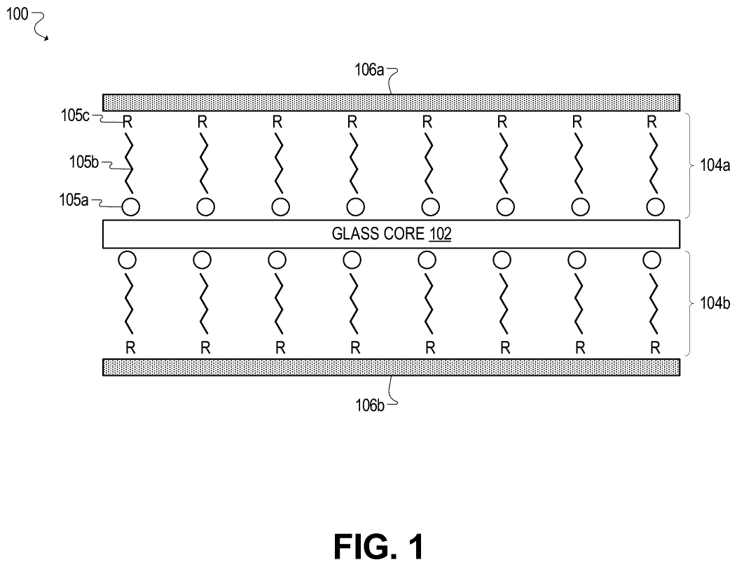

FIG. 1 illustrates a cross-section view of a substrate 100 with a glass core and self-assembled monolayers to provide adhesion to copper seed layers in accordance with certain embodiments. In the illustrated embodiment, for example, the substrate 100 includes a glass core 102, self-assembled monolayers 104a-b formed above and below the glass core 102, and copper seed layers 106a-b formed above and below the self-assembled monolayers 104a-b. The self-assembled monolayers 104a-b are bonded to the glass core 102 and provide adhesion to the copper seed layers 106a-b.

A self-assembled monolayer (SAM) 104 is a self-organizing layer of molecules formed spontaneously on, and bonded to, the surface of a substrate. The molecules in a SAM 104 generally include a head group 105a, a tail group 105b, and a functional end group 105c. Further, a SAM may be formed by the chemisorption of the head groups 105a onto the substrate from either the vapor or liquid phase, followed by a slow organization of the tail groups 105b.

In some embodiments, the SAMs 104a-b are formed via deposition of R group-terminated organosilanes on the glass core 102, where R can be any functional group except alkanes. In this manner, the SAMs 104a-b form on and bond to the glass core 102 via the head groups 105a. Further, the presence of the functional group 105c in the SAMs 104a-b promotes the epitaxial growth of copper film by coordinating the Cu(II) ions. As a result, the SAMs 104a-b act as an adhesion promoter for depositing the copper seed layers 106a-b on the glass core 102.

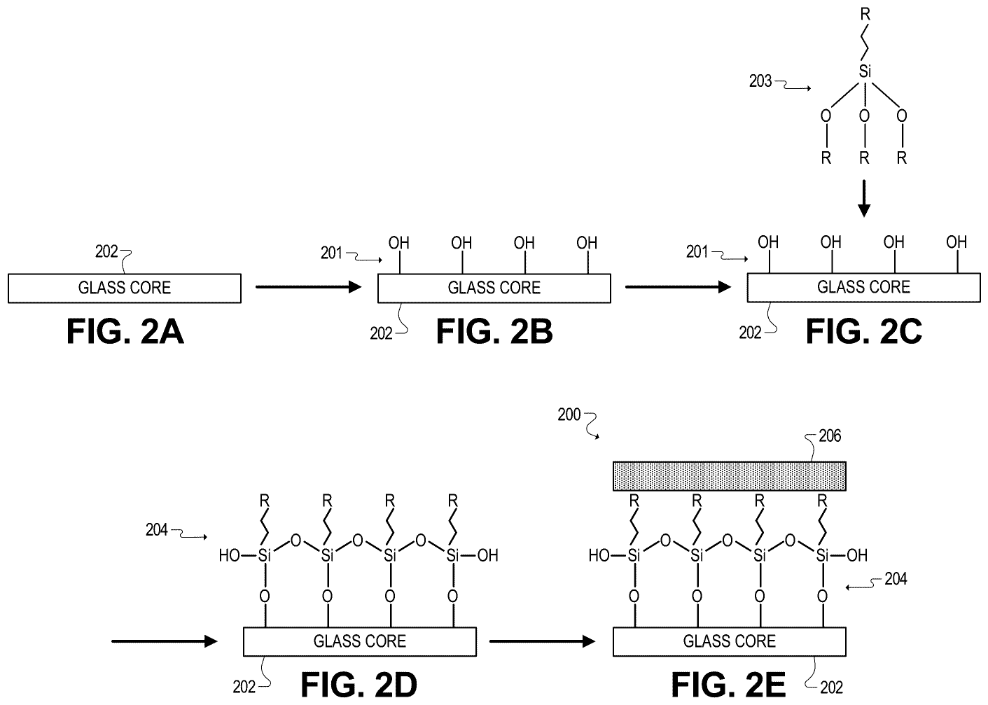

Controlled formation of the SAMs 104a-b on the glass core 102 can be achieved using vacuum vapor deposition or solution-based deposition. Further, patterning of SAMs 104a-b for targeted copper deposition can be achieved using either aliphatic SAMs, which degrade upon exposure to electrons (positive resist behavior), or aromatic SAMs, which become more stable upon electron exposure (negative resist behavior). As an example, patterning and removal of aliphatic SAMs can be performed using electron beams or lasers. The copper seed layers 106a-b can then be formed by depositing copper film on the SAMs 104a-b using atomic layer deposition (ALD) or chemical vapor deposition (CVD). The process of forming the SAMs 104a-b and the copper seed layers 106a-b on the glass core 102 is described in further detail in connection with FIGS. 2A-D.

The use of R group-terminated organosilanes to form SAMs 104a-b for adhesion promotion between a glass core 102 and copper seed layers 106a-b provides various advantages. In particular, self-assembled monolayers not only promote adhesion between the glass core and the copper seed layers, but they are also significantly thinner than adhesive titanium layers. For example, the thickness of adhesive layers formed using self-assembled monolayers can be controlled to less than 25 nm, which helps reduce the size of the resulting substrate and integrated circuit package. In some cases, the thickness of these self-assembled monolayers can be controlled to less than 10 nm for multilayers, and even 1 nm or less for short chain monolayers. In addition, the use of self-assembled monolayers for glass/copper adhesion is a cheaper alternative than titanium, as self-assembled monolayers can be deposited using solution-based methods as well as CVD. Further, organosilanes used to form self-assembled monolayers are readily available and cost effective. A glass core substrate with adhesive self-assembled monolayers can be detected based on the presence of an organic interlayer between the glass core and the first copper layer, along with the identity of the elements and functional groups present on the surface of the glass core.

FIGS. 2A-E illustrate a process flow for forming a glass substrate 200 with a self-assembled monolayer and a copper seed layer in accordance with certain embodiments. In the illustrated process flow, organosilanes are deposited on a hydrolyzed glass core 202 to form a self-assembled monolayer (SAM) 204 on the glass core 202, which promotes adhesion to a subsequent copper seed layer 206 formed by depositing copper on the SAM 204. While the illustrated process flow only shows the SAM 204 and copper seed layer 206 being formed above the glass core 202, this process flow can be used to form SAMs and copper seed layers above and below the glass core (e.g., similar to substrate 100 of FIG. 1).

In the illustrated process flow, deposition of organosilane precursors 203 is used to form a self-assembled monolayer (SAM) 204 on the glass core 202 to promote adhesion between the glass core 202 and the copper seed layer 206. This process requires the glass core 202 to have a hydroxyl-terminated surface in order for the organosilanes to attach to the glass core 202 and form the SAM 204. A hydroxyl-terminated surface is a surface that terminates with hydroxyl groups (—OH), which are functional groups composed of one oxygen atom covalently bonded to one hydrogen atom. Hydroxyl groups (—OH) can be formed by treating the surface of the glass core 202 with Piranha solution, hydrogen fluoride, or plasma (e.g., oxygen plasma). Organosilanes can then be deposited on the hydrolyzed glass core 202 to form the SAM 204, and copper can be deposited on the SAM 204 to form the copper seed layer 206.

In FIG. 2A, the process flow begins by providing a glass core 202 (e.g., a substrate formed of one or more layers of glass).

In FIG. 2B, the glass core 202 is treated with Piranha solution, hydrogen fluoride, or plasma (e.g., oxygen plasma) to hydrolyze the glass core 202 and form hydroxyl groups (—OH) 201 on its surface.

In FIG. 2C, organosilanes 203 are deposited on the hydrolyzed glass core 202 to cause a self-assembled monolayer to form. A self-assembled monolayer can be formed on a hydrolyzed glass surface 202 by depositing R group-terminated organosilanes 203, where R can be any functional group except alkanes (e.g., R=−SH, −SO₃H, —N₃, —NH₂, —CN, —RCOO, or —COOH). The reaction of the R group-terminated organosilanes 203 with the hydrolyzed glass core 202 involves the formation of polysiloxane, which attaches to the silanol groups (—SiOH) on the surface of the glass core 202. A silanol group (—SiOH) is a functional group composed of silicon, oxygen, and hydrogen atoms.

Examples of organosilanes that can be used for SAM formation on glass include, without limitation:
(3-aminopropyl)trimethoxysilane (C₆H₁₇NO₃Si);
(3-aminopropyl)triethoxysilane (C₉H₂₃NO₃Si);
(3-mercaptopropyl)trimethoxysilane (C₆H₁₆O₃SSi);
carboxyethylsilanetriol (C₃H₈O₅Si);
(3-azidopropyl)triethoxysilane (C₉H₂₁N₃O₃Si);
(3-acryloxypropyl)methyldimethoxysilane (C₉H₁₈O₄Si);
(3-acetoxypropyl)trimethoxysilane (C₈H₁₇O₅Si);
(3-aminopropyl)diisopropylethoxysilane (C₁₁H₂₇NOSi); and
(3-aminopropyl)dimethylethoxysilane (C₇H₁₉NOSi).

Deposition of organosilanes 203 can be performed using vacuum vapor deposition or solution-based deposition. For example, the hydroxl-terminated glass core 202 can be dipped in organosilane solution or treated with organosilane vapors for a prolonged time to form self-assembled monolayers. Vacuum vapor deposition of organosilanes is usually performed at working pressures between 2-3 Torr and temperatures less than 100° C., and often relies on continuous delivery of the reactants (0.1 to 5 mL injected volume) for approximately 5 minutes. This enables controlled deposition of organosilane precursors to achieve compact monolayer formation on the surface of the glass core 202.

In FIG. 2D, the self-assembled monolayer 204 has been fully formed on the glass core 202 based on deposition of the organosilanes 203 on the hydrolyzed glass core 202 in FIG. 2C.

In FIG. 2E, copper is deposited on the self-assembled monolayer 204 using ALD or CVD methods to form a copper seed layer 206. In some embodiments, for example, copper seed deposition may be performed using ALD or CVD at a pressure of 400 pascals (Pa), temperature of 300-500° C., and hydrogen gas (H₂) flow rate of 20 standard cubic centimeters per minute (SCCM) for approximately 15 minutes using copper(II) bis-hexafluoroacetatylacetonate as a precursor. Further, in some embodiments, copper seed deposition may be performed using dry methods (e.g., plasma) instead of wet chemistry methods.

The completed substrate 200 is shown in FIG. 2E, which includes the glass core 202, self-assembled monolayer 204, and copper seed layer 206.

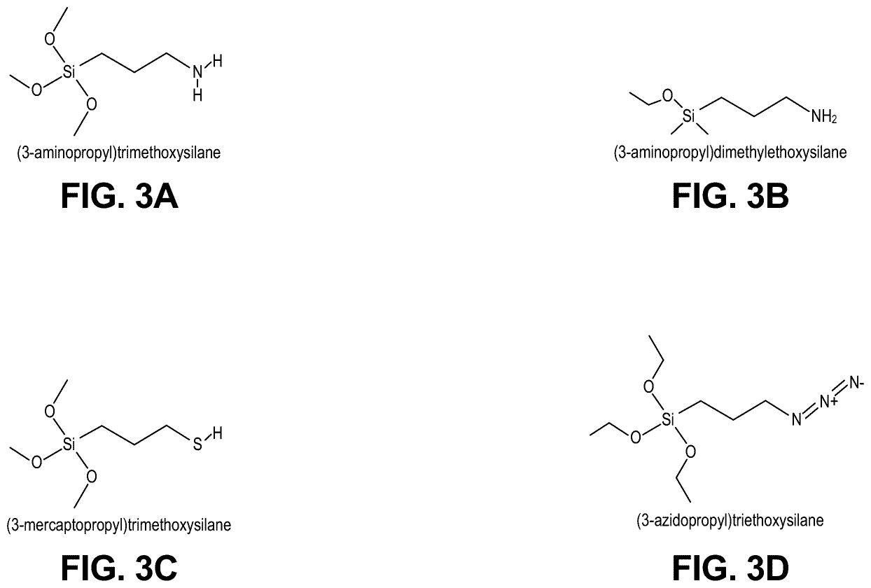

FIGS. 3A-D illustrate the molecular structure of various representative organosilanes that may be used to form self-assembled monolayers on glass substrates in accordance with embodiments described herein. In FIG. 3A particular, illustrates (3-aminopropyl)trimethoxysilane, FIG. 3B illustrates (3-aminopropyl)dimethylethoxysilane, FIG. 3C illustrates (3-mercaptopropyl)trimethoxysilane, and FIG. 3D illustrates (3-azidopropyl)triethoxysilane.

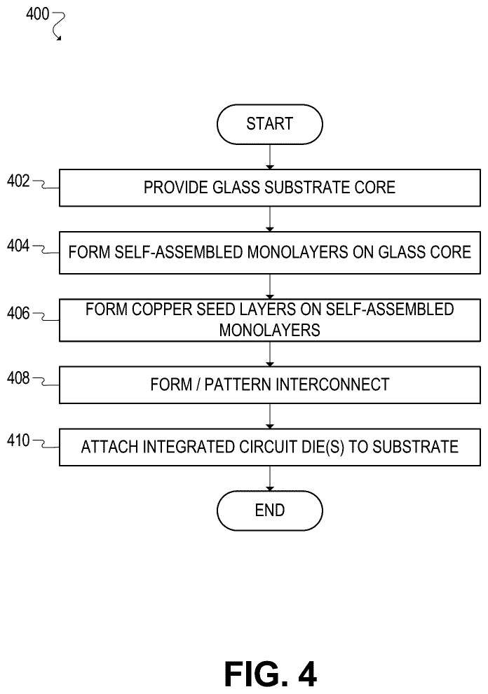

FIG. 4 illustrates a flowchart 400 for forming an integrated circuit (IC) package on a substrate with a glass core and self-assembled monolayers for adhesion to copper seed layers. It will be appreciated in light of this disclosure that flowchart 400 is only one example methodology for arriving at an IC package on the example glass core substrates shown and described throughout this disclosure.

The steps of flowchart 400 may be performed using any suitable semiconductor fabrication techniques. For example, film deposition—such as depositing layers, filling portions of layers (e.g., removed portions), and filling via openings—may be performed using any suitable deposition techniques, including, for example, electroless deposition, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 402 by providing and/or forming a glass core for a package substrate. In some embodiments, for example, the glass core may include one or more layers of glass.

The flowchart then proceeds to block 404 to form self-assembled monolayers on the top and bottom surfaces of the glass core. In some embodiments, the surfaces of the glass core are hydrolyzed to form hydroxyl-terminated surfaces on the glass core, or surfaces that terminate with hydroxyl groups. For example, the surfaces of the glass core may be hydrolyzed by treating them with Piranha solution, hydrogen fluoride, or plasma (e.g., oxygen plasma). Next, organosilanes are deposited on the treated surfaces of the glass core, which in turn causes self-assembled monolayers to form on the glass core.

In some embodiments, depending on the particular organosilanes used to form the self-assembled monolayers, the resulting self-assembled monolayers may include silicon, oxygen, sulfur, hydrogen, nitrogen, and/or carbon. Further, in some embodiments, each self-assembled monolayer may have a thickness of 10-25 nanometers or less, and in some cases, a self-assembled monolayer may have a thickness of 1 nanometer or less.

The flowchart then proceeds to block 406 to form conductive seed layers on the self-assembled monolayers. In some embodiments, the conductive seed layers may be formed by depositing a conductive material, such as a material that includes copper and/or other suitable metal(s), on the self-assembled monolayers.

In this manner, the resulting substrate includes the glass core and respective stacks of layers above and below the glass core. For example, each stack of layers above and below the core includes a self-assembled monolayer and a conductive copper seed layer. Further, the self-assembled monolayers are between the glass core and the copper seed layers, thus providing adhesion between the core and the seed layers.

The flowchart then proceeds to block 408 to form and pattern interconnect layers and structures (e.g., metallization processing) on the resulting glass core substrate. In this manner, conductive traces/interconnects are formed on the substrate, thus forming a completed package substrate.

For example, through holes in the glass core may be formed and/or filled with metal to form through-hole vias through the core. In addition, a series of alternating/interleaving dielectric (e.g., buildup, prepreg) and conductive layers may be formed above and/or below the core (e.g., with conductive layers separated by dielectric layers). Further, vias may be formed through the dielectric layers to form electrical connections between certain conductive layers (e.g., blind vias, buried vias, through-hole vias). Finally, conductive contacts may be formed on the top and/or bottom surfaces of the substrate (e.g., solder balls/bumps, metal pads). In some embodiments, the metallization layers and structures may be formed using metals such as copper, titanium, tin, silver, gold, nickel, aluminum, and/or tungsten.

The dielectric/buildup layers, conductive layers, vias, and conductive contacts collectively form conductive traces or interconnects on the glass core substrate (e.g., horizontal traces formed by the conductive layers, vertical traces formed by the vias, etc.). The completed package substrate includes the glass core with self-assembled monolayers and copper seed layers, along with the various interconnect layers and structures (e.g., dielectric/buildup layers, conductive layers, vias, surface contacts) formed above and/or below the glass core.

The flowchart then proceeds to block 410 to attach one or more integrated circuit (IC) dies to the completed package substrate. For example, the package substrate and IC die(s) may be assembled such that the conductive contacts on the IC die(s) are electrically coupled to the conductive contacts on the surface of the package substrate. The completed IC package may subsequently be attached to or included as part of a printed circuit board or another integrated circuit substrate, package, or device (e.g., electronic devices 700, 1100).

At this point, the flowchart may be complete. In some embodiments, however, the flowchart may restart and/or certain blocks may be repeated. For example, in some embodiments, the flowchart may restart at block 402 to form another integrated circuit package with the same or similar design.

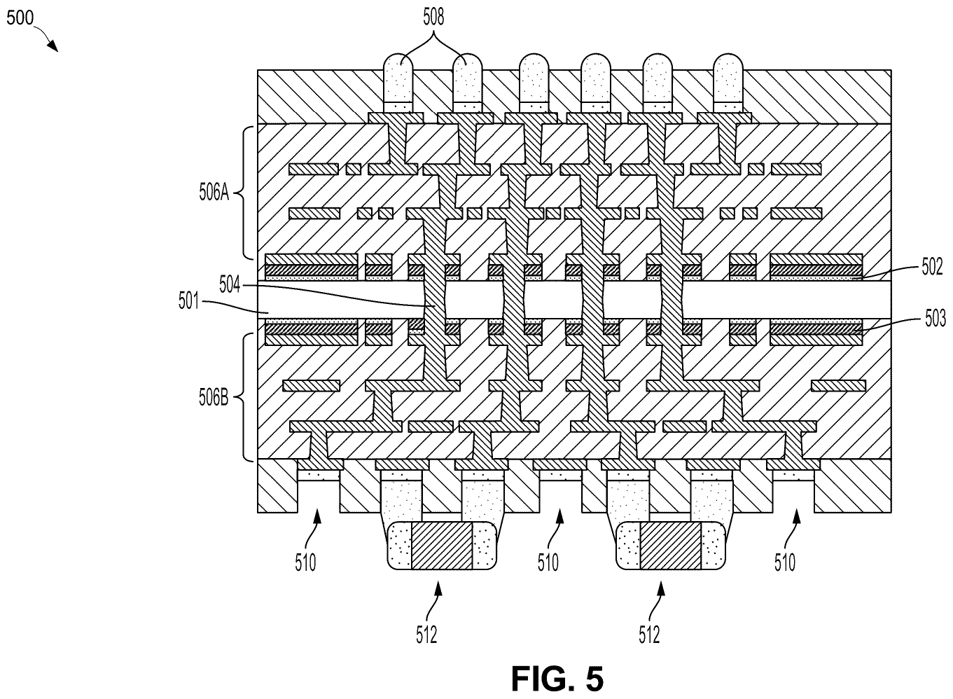

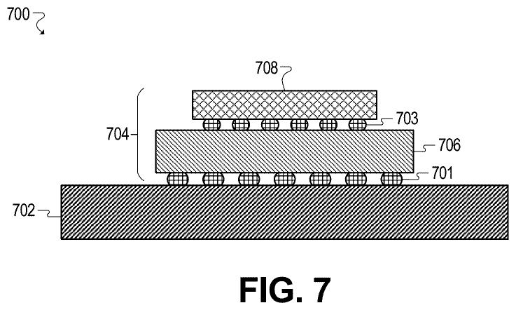

FIG. 5 illustrates an example of a package substrate 500 with a glass core and self-assembled monolayers in accordance with certain embodiments. The example package substrate 500 includes a glass core 501 with self-assembled monolayers 502 on the top and bottom surfaces of the core 501 for adhesion to copper seed layers 503. Build-up layers 506 are formed above and below the glass core 501, with build-up layers 506A on above the core 501 and build-up layers 506B on below the core 501. The layers 506 may be made from any suitable dielectric material, such as a traditional organic BU material in certain embodiments. The layers 506 include metal pillars, vias, and/or traces 504 as shown to electrically couple the solder bumps 508 at the top of the package substrate 500 with the pads 510 at the bottom of the substrate. In certain instances, for example, an integrated circuit die may be coupled to a top side of the package substrate 500 and connected to the solder bumps 508, and the package substrate 500 may be coupled to a circuit board (e.g., a motherboard, main board, etc.) via the pads 510 at the bottom of the package substrate 500. For instance, the package substrate 500 may be incorporated into the device 700 of FIG. 7 as package substrate 706. The package substrate 500 also includes land side capacitors 512 coupled on a bottom side of the package substrate 500.

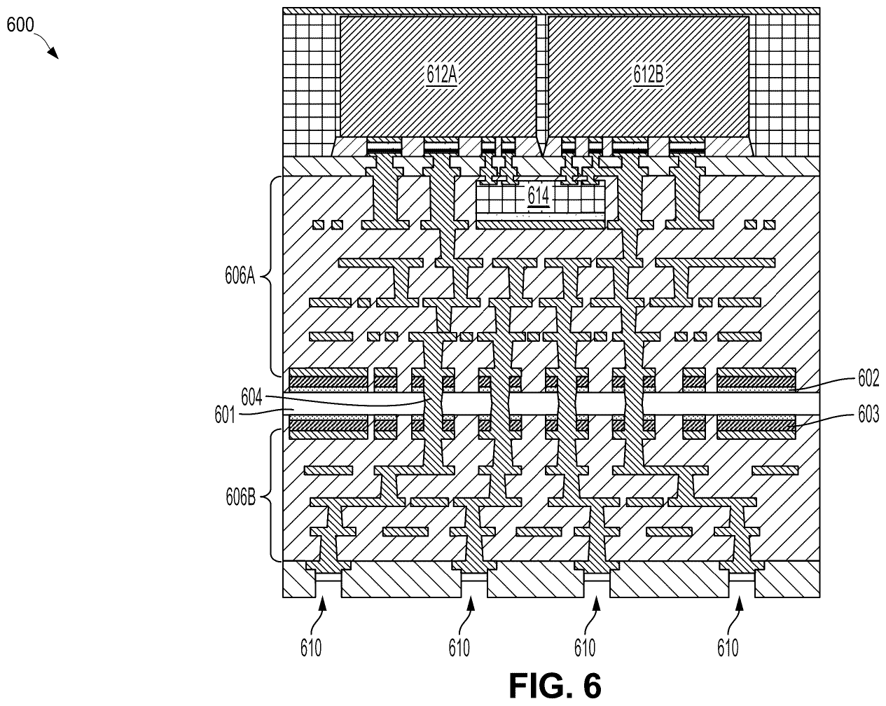

FIG. 6 illustrates an example of a multi-die package 600 on a substrate with a glass core and self-assembled monolayers in accordance with certain embodiments. The multi-die package 600 includes a glass core 601 with self-assembled monolayers 602 on the top and bottom surfaces of the core 601 for adhesion to copper seed layers 603. The multi-die package 600 further includes build-up layers 606 above and below the core 601, with build-up layers 606A formed above the core 601 and build-up layers 606B formed below the core 601. The build-up layers 606 may be formed using any suitable dielectric materials, such as traditional organic materials. The layers 606 include metal pillars, vias, and/or traces 604 as shown to electrically couple the integrated circuit (IC) dies 612 at the top of the multi-die package 600 with the pads 610 at the bottom of the package 600.

In addition, the package 600 includes a bridge component 614 in the build-up layers 606A, which electrically couples the first IC die 612A with the second IC die 612B. The bridge component 614 may include passive and/or active components to interconnect the IC dies 612. The bridge component 614 may be an Intel® embedded multi-die interconnect bridge (EMIB) in certain embodiments. In certain instances, the multi-die package 600 may be coupled to a circuit board (e.g., a motherboard, main board, etc.) via the pads 610 at the bottom of the package 600. For instance, the package 600 may be incorporated into the device 700 of FIG. 7 as a multi-die package 704 with multiple integrated circuit dies 708.

FIG. 7 illustrates a cross-section view of an electronic device 700 in accordance with certain embodiments. The electronic device 700 includes an integrated circuit package 704 electrically coupled to a board 702. The integrated circuit package 704 includes a package substrate 706 and an integrated circuit die 708 electrically coupled to the package substrate 706. In some embodiments, the integrated circuit package 704 may be implemented as a multi-die package with multiple integrated circuit dies 708 and associated interconnects.

In some embodiments, the package substrate 706 may be a cored packaged substrate, such as a package substrate with a glass core. For example, the package substrate 706 may include a glass core with self-assembled monolayers for adhesion to copper seed layers according to embodiments described throughout this disclosure. Further, in some embodiments, the board 702 may also be implemented with a glass core according to embodiments described throughout this disclosure.

In some embodiments, the board 702 may be a printed circuit board (PCB), motherboard, mainboard, or the like. The package substrate 706 is connected to the board 702 by conductive contacts 701, which may be referred to as second level interconnects (SLIs). In the illustrated embodiment, the interconnects 701 are shown as solder bumps, but it is to be appreciated that any interconnect architecture may be used (e.g., wire bonds, sockets, etc.).

The integrated circuit die 708 is electrically coupled to the package substrate 706 by conductive contacts 703, which may be referred to as first level interconnects (FLIs). The interconnects 703 may include solder, nickel, copper bumps, and/or the like, but it is to be appreciated that any interconnect architecture may be used.

The integrated circuit die 708 may include any suitable type of circuitry, including, but not limited to, processing circuitry, communication circuitry, and/or memory/storage circuitry. In some embodiments, for example, the integrated circuit die 708 may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples.

The package substrate 706 may provide electrical connections between the die 708 and the circuit board 702. Further, the circuit board 702 may provide electrical connections to other components of a computer system, such as processors, memory, storage, network interface controllers, peripheral devices, power supplies, etc. The circuit board 702 may include one or more conductive traces and circuit components to provide interconnects between such computer system components.

The electronic device 700 may be any type of electronic device, including, but not limited to, a cell phone, a wearable device, a computer, a server, a camera, a video playback device, a video game console, a display device, a vehicle control unit, or an appliance.

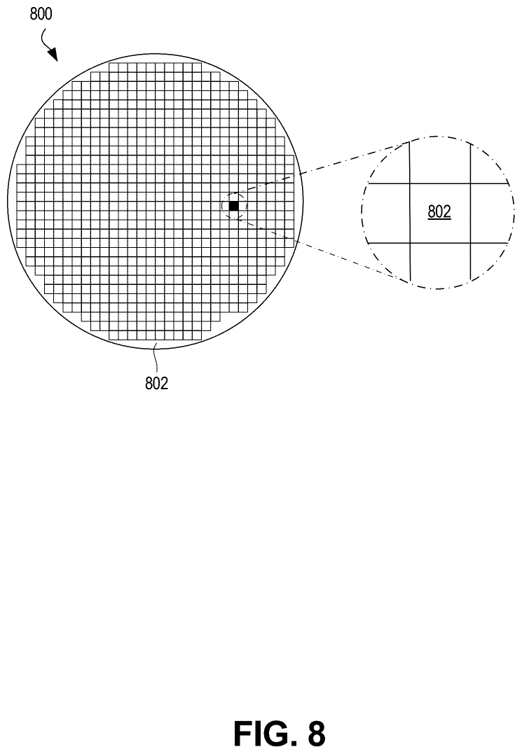

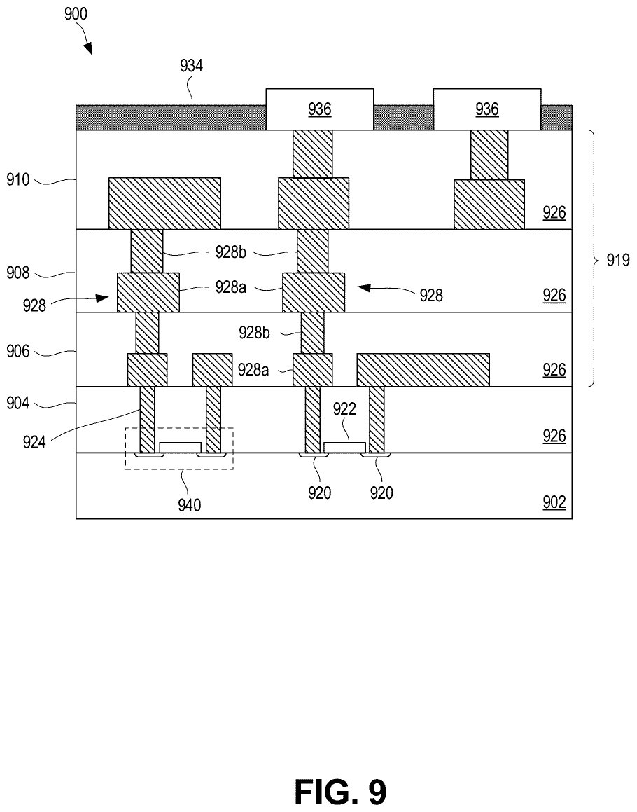

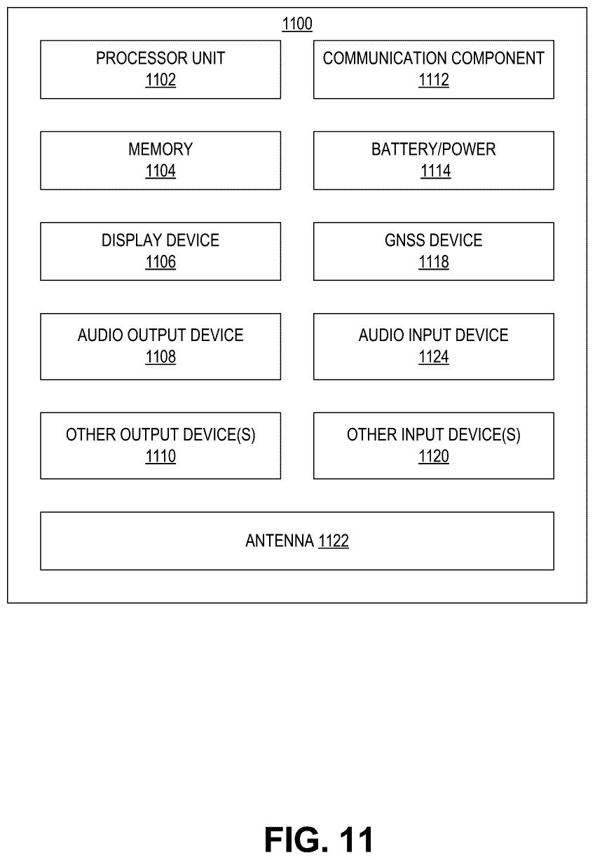

FIG. 8 is a top view of a wafer 800 and dies 802 that may be included in any of the embodiments disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may be any of the dies disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1102 of FIG. 11) or other logic that is configured to store information in the memory devices or execute instructions stored in the memory array. Various ones of the microelectronic assemblies disclosed herein may be manufactured using a die-to-wafer assembly technique in which some dies are attached to a wafer 800 that include others of the dies, and the wafer 800 is subsequently singulated.

FIG. 9 is a cross-sectional side view of an integrated circuit device 900 that may be included in any of the embodiments disclosed herein (e.g., in any of the dies). One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components. The conductive contacts 936 may serve as any of the conductive contacts described throughout this disclosure.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936. These additional conductive contacts may serve as any of the conductive contacts described throughout this disclosure.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. These additional conductive contacts may serve as any of the conductive contacts described throughout this disclosure. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

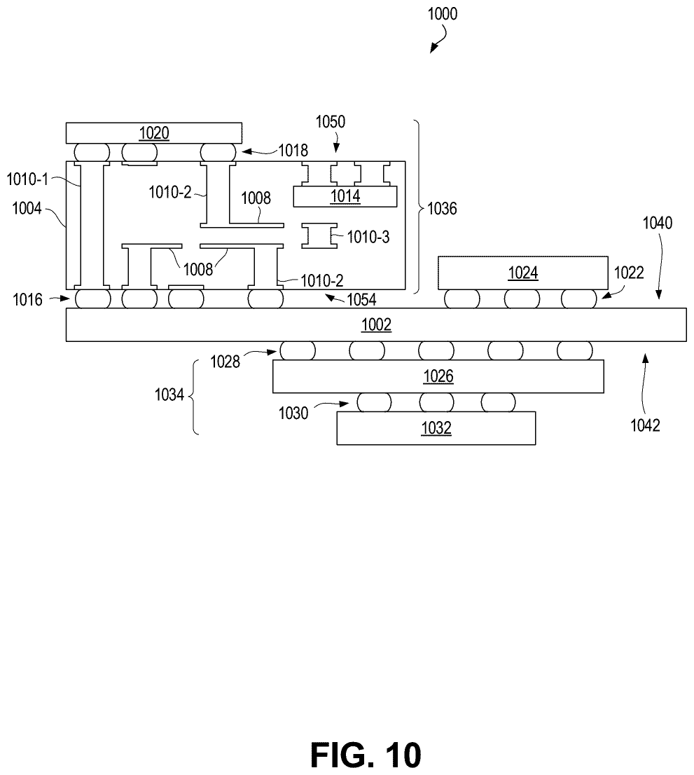

FIG. 10 is a cross-sectional side view of an integrated circuit device assembly 1000 that may include any of the embodiments disclosed herein. For example, any suitable component of integrated circuit device assembly 1000 may include one or more of the glass core substrates 100, 200 disclosed herein. In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies 100 disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more of the glass core substrates 100, 200, package substrates 500, integrated circuit packages 600, electronic devices 700, integrated circuit device assemblies 1000, integrated circuit components 1020, integrated circuit devices 900, or integrated circuit dies 802 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include other output device(s) 1110 (or corresponding interface circuitry, as discussed above). Examples of the other output device(s) 1110 may include an audio codec, a video codec, a printer, a wired or wireless transmitter for providing information to other devices, or an additional storage device.

The electrical device 1100 may include other input device(s) 1120 (or corresponding interface circuitry, as discussed above). Examples of the other input device(s) 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

### EXAMPLE EMBODIMENTS

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a substrate, comprising: one or more glass layers; a self-assembled monolayer on the one or more glass layers; and a conductive layer on the self-assembled monolayer, wherein the conductive layer comprises copper, and wherein the self-assembled monolayer is between the one or more glass layers and the conductive layer.

Example 2 includes the substrate of Example 1, wherein the self-assembled monolayer comprises silicon and oxygen.

Example 3 includes the substrate of Example 2, wherein the self-assembled monolayer further comprises sulfur, hydrogen, nitrogen, or carbon.

Example 4 includes the substrate of Example 2, wherein the self-assembled monolayer further comprises: sulfur and hydrogen; nitrogen and hydrogen; carbon and nitrogen; or carbon and hydrogen.

Example 5 includes the substrate of any of Examples 1-4, wherein the self-assembled monolayer has a thickness of 25 nanometers or less.

Example 6 includes the substrate of any of Examples 1-5, wherein the self-assembled monolayer has a thickness of 1 nanometer or less.

Example 7 includes the substrate of any of Examples 1-6, wherein: the self-assembled monolayer is a first self-assembled monolayer; the conductive layer is a first conductive layer; and the substrate further comprises: a glass core comprising the one or more glass layers; a first stack of layers above the glass core, wherein the first stack of layers includes the first self-assembled monolayer and the first conductive layer, wherein the first self-assembled monolayer is between the glass core and the first conductive layer; and a second stack of layers below the glass core, wherein the second stack of layers includes a second self-assembled monolayer and a second conductive layer, wherein the second conductive layer comprises copper, and wherein the second self-assembled monolayer is between the glass core and the second conductive layer.

Example 8 includes the substrate of Example 7, wherein: the substrate is a package substrate, wherein the package substrate is to be electrically coupled to one or more integrated circuit dies; and the package substrate further comprises: one or more conductive traces; and one or more conductive contacts on a surface of the package substrate.

Example 9 includes an integrated circuit package, comprising: an integrated circuit die; and a package substrate electrically coupled to the integrated circuit die, wherein the package substrate comprises: a glass core comprising one or more glass layers; a first stack of layers above the glass core, wherein the first stack of layers includes: a first self-assembled monolayer; and a first conductive layer comprising copper, wherein the first self-assembled monolayer is between the glass core and the first conductive layer; a second stack of layers below the glass core, wherein the second stack of layers includes: a second self-assembled monolayer; and a second conductive layer comprising copper, wherein the second self-assembled monolayer is between the glass core and the second conductive layer; a plurality of dielectric layers, wherein at least some of the dielectric layers are above the glass core and at least some of the dielectric layers are below the glass core; and one or more conductive traces.

Example 10 includes the integrated circuit package of Example 9, wherein the first and second self-assembled monolayers comprise silicon and oxygen.

Example 11 includes the integrated circuit package of Example 10, wherein the first and second self-assembled monolayers further comprise sulfur, hydrogen, nitrogen, or carbon.

Example 12 includes the integrated circuit package of Example 10, wherein the first and second self-assembled monolayers further comprise: sulfur and hydrogen; nitrogen and hydrogen; carbon and nitrogen; or carbon and hydrogen.

Example 13 includes the integrated circuit package of any of Examples 9-12, wherein the first and second self-assembled monolayers each have a thickness of 25 nanometers or less.

Example 14 includes the integrated circuit package of any of Examples 9-13, wherein the first and second self-assembled monolayers each have a thickness of 1 nanometer or less.

Example 15 includes the integrated circuit package of any of Examples 9-14, wherein the one or more conductive traces comprise: one or more horizontal traces; one or more vias; and one or more conductive contacts on a surface of the package substrate.

Example 16 includes an electronic device, comprising: a board; and an integrated circuit package coupled to the board, wherein the integrated circuit package comprises: an integrated circuit die; and a package substrate electrically coupled to the integrated circuit die, wherein the package substrate comprises: a glass core comprising one or more glass layers; a first stack of layers above the glass core, wherein the first stack of layers includes: a first self-assembled monolayer; and a first conductive layer comprising copper, wherein the first self-assembled monolayer is between the glass core and the first conductive layer; a second stack of layers below the glass core, wherein the second stack of layers includes: a second self-assembled monolayer; and a second conductive layer comprising copper, wherein the second self-assembled monolayer is between the glass core and the second conductive layer; a plurality of dielectric layers, wherein at least some of the dielectric layers are above the glass core and at least some of the dielectric layers are below the glass core; and one or more conductive traces.

Example 17 includes the electronic device of Example 16, wherein the first and second self-assembled monolayers comprise silicon and oxygen.

Example 18 includes the electronic device of Example 17, wherein the first and second self-assembled monolayers further comprise sulfur, hydrogen, nitrogen, or carbon.

Example 19 includes the electronic device of Example 17, wherein the first and second self-assembled monolayers further comprise: sulfur and hydrogen; nitrogen and hydrogen; carbon and nitrogen; or carbon and hydrogen.

Example 20 includes the electronic device of any of Examples 16-19, wherein the integrated circuit die comprises processing circuitry, communication circuitry, or memory circuitry.

Example 21 includes the electronic device of any of Examples 16-20, wherein the electronic device is a cell phone, a wearable device, a computer, a server, a camera, a video playback device, a video game console, a display device, a vehicle control unit, or an appliance.

Example 22 includes a method of forming a substrate, comprising: providing a glass core; forming a self-assembled monolayer on the glass core; and forming a conductive layer on the self-assembled monolayer, wherein the conductive layer comprises copper, and wherein the self-assembled monolayer is between the glass core and the conductive layer.

Example 23 includes the method of Example 22, wherein providing the glass core comprises: forming the glass core, wherein the glass core comprises one or more glass layers.

Example 24 includes the method of any of Examples 22-23, wherein forming the self-assembled monolayer on the glass core comprises: treating a surface of the glass core with Piranha solution, hydrogen fluoride, or plasma; and depositing organosilanes on the treated surface of the glass core.

Example 25 includes the method of any of Examples 22-24, wherein the self-assembled monolayer comprises: silicon; oxygen; and at least one of sulfur, hydrogen, nitrogen, or carbon.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate may include solder bumps (or other conductive contacts) as bonding interconnects on one or both sides. One side of the substrate, generally referred to as the “die side”, may include solder bumps for chip or die bonding. The opposite side of the substrate, generally referred to as the “land side”, may include solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. A substrate, comprising:
one or more glass layers;
a self-assembled monolayer on the one or more glass layers; and
a conductive layer on the self-assembled monolayer, wherein the conductive layer comprises copper, and wherein the self-assembled monolayer is between the one or more glass layers and the conductive layer.

2. The substrate of claim 1, wherein the self-assembled monolayer comprises silicon and oxygen.

3. The substrate of claim 2, wherein the self-assembled monolayer further comprises sulfur, hydrogen, nitrogen, or carbon.

4. The substrate of claim 2, wherein the self-assembled monolayer further comprises:
sulfur and hydrogen;
nitrogen and hydrogen;
carbon and nitrogen; or
carbon and hydrogen.

5. The substrate of claim 1, wherein the self-assembled monolayer has a thickness of 25 nanometers or less.

6. The substrate of claim 1, wherein the self-assembled monolayer has a thickness of 1 nanometer or less.

7. The substrate of claim 1, wherein:
the self-assembled monolayer is a first self-assembled monolayer;
the conductive layer is a first conductive layer; and
the substrate further comprises:
a glass core comprising the one or more glass layers;
a first stack of layers above the glass core, wherein the first stack of layers includes the first self-assembled monolayer and the first conductive layer, wherein the first self-assembled monolayer is between the glass core and the first conductive layer; and
a second stack of layers below the glass core, wherein the second stack of layers includes a second self-assembled monolayer and a second conductive layer, wherein the second conductive layer comprises copper, and wherein the second self-assembled monolayer is between the glass core and the second conductive layer.

8. The substrate of claim 7, wherein:
the substrate is a package substrate, wherein the package substrate is to be electrically coupled to one or more integrated circuit dies; and
the package substrate further comprises:
one or more conductive traces; and
one or more conductive contacts on a surface of the package substrate.

9. An integrated circuit package, comprising:
an integrated circuit die; and
a package substrate electrically coupled to the integrated circuit die, wherein the package substrate comprises:
a glass core comprising one or more glass layers;
a first stack of layers above the glass core, wherein the first stack of layers includes:
a first self-assembled monolayer; and
a first conductive layer comprising copper, wherein the first self-assembled monolayer is between the glass core and the first conductive layer;
a second stack of layers below the glass core, wherein the second stack of layers includes:
a second self-assembled monolayer; and
a second conductive layer comprising copper, wherein the second self-assembled monolayer is between the glass core and the second conductive layer;
a plurality of dielectric layers, wherein at least some of the dielectric layers are above the glass core and at least some of the dielectric layers are below the glass core; and
one or more conductive traces.

10. The integrated circuit package of claim 9, wherein the first and second self-assembled monolayers comprise silicon and oxygen.

11. The integrated circuit package of claim 10, wherein the first and second self-assembled monolayers further comprise:
sulfur and hydrogen;
nitrogen and hydrogen;
carbon and nitrogen; or
carbon and hydrogen.

12. The integrated circuit package of claim 9, wherein the first and second self-assembled monolayers each have a thickness of 25 nanometers or less.

13. The integrated circuit package of claim 9, wherein the one or more conductive traces comprise:
one or more horizontal traces;
one or more vias; and
one or more conductive contacts on a surface of the package substrate.

14. An electronic device, comprising:
a board; and
an integrated circuit package coupled to the board, wherein the integrated circuit package comprises:
an integrated circuit die; and
a package substrate electrically coupled to the integrated circuit die, wherein the package substrate comprises:
a glass core comprising one or more glass layers;
a first stack of layers above the glass core, wherein the first stack of layers includes:
a first self-assembled monolayer; and
a first conductive layer comprising copper, wherein the first self-assembled monolayer is between the glass core and the first conductive layer;
a second stack of layers below the glass core, wherein the second stack of layers includes:
a second self-assembled monolayer; and
a second conductive layer comprising copper, wherein the second self-assembled monolayer is between the glass core and the second conductive layer;
a plurality of dielectric layers, wherein at least some of the dielectric layers are above the glass core and at least some of the dielectric layers are below the glass core; and
one or more conductive traces.

15. The electronic device of claim 14, wherein the first and second self-assembled monolayers comprise:
silicon;
oxygen; and
at least one of sulfur, hydrogen, nitrogen, or carbon.

16. The electronic device of claim 14, wherein the integrated circuit die comprises processing circuitry, communication circuitry, or memory circuitry.

17. The electronic device of claim 14, wherein the electronic device is a cell phone, a wearable device, a computer, a server, a camera, a video playback device, a video game console, a display device, a vehicle control unit, or an appliance.

18. A method of forming a substrate, comprising:
providing a glass core;
forming a self-assembled monolayer on the glass core; and
forming a conductive layer on the self-assembled monolayer, wherein the conductive layer comprises copper, and wherein the self-assembled monolayer is between the glass core and the conductive layer.

19. The method of claim 18, wherein forming the self-assembled monolayer on the glass core comprises:
treating a surface of the glass core with Piranha solution, hydrogen fluoride, or plasma; and
depositing organosilanes on the treated surface of the glass core.

20. The method of claim 18, wherein the self-assembled monolayer comprises:
silicon;
oxygen; and
at least one of sulfur, hydrogen, nitrogen, or carbon.
